(19) United States
(12) Patent Application Publication
(10) Pub. No.: US 2015/0243933 A1
(43) Pub. Date: Aug. 27, 2015

(54) ORGANIC LIGHT-EMITTING DISPLAY APPARATUS

(71) Applicant: Samsung Display Co., Ltd., Yongin-city (KR)

(72) Inventors: Jun-Han LEE, Yongin-city (KR); Mun-Ki SIM, Yongin-city (KR); Baek-Hee LEE, Yongin-city (KR); Jae-Byung PARK, Yongin-city (KR); Seon-Tae YOON, Yongin-city (KR); Kwang-Keun LEE, Yongin-city (KR); Hyun-Min CHO, Yongin-city (KR)

(21) Appl. No.: 14/494,972

(22) Filed: Sep. 24, 2014

(30) Foreign Application Priority Data
Feb. 24, 2014 (KR) 10-2014-0021518

(51) Int. Cl. H01L 51/52

(52) U.S. Cl. CPC H01L 51/5293; H01L 51/524; H01L 51/5271

(57) ABSTRACT

An organic light-emitting display apparatus includes: a substrate including a first surface and a second surface opposite to each other; an organic emission unit disposed on the first surface of the substrate and including: an emission region configured to emit light; and a first transmission region configured to transmit external light; an encapsulation unit joined to the first surface of the substrate, the encapsulating unit configured to seal the organic emission unit from external air; a first optical layer configured to delay a phase of the external light; and a second functional layer configured to linearly polarize the external light, wherein the second function layer is disposed farther from the organic emission unit than the first functional layer and includes a second transmission region corresponding to the first transmission region.

### CROSS REFERENCE TO RELATED APPLICATION

This application claims priority from and the benefit of Korean Patent Application No. 10-2014-0021518, filed on Feb. 24, 2014, which is hereby incorporated by reference for all purposes as if fully set forth herein.

### BACKGROUND

1. Field

Exemplary embodiments of the present invention relate to organic light-emitting display apparatuses.

2. Discussion of the Background

An organic light-emitting display apparatus is a self-luminous display apparatus that emits light by electrically exciting an organic compound. Since the organic light-emitting display apparatus may be driven at a low voltage, may be made to be thin, and has a wide viewing angle and a high response speed, the organic light-emitting display apparatus may solve the problems of a liquid crystal display (LCD) apparatus. There have been attempts to form an organic light-emitting display apparatus as a transparent display apparatus.

Generally in the organic light-emitting display apparatus, a circular polarization film may be attached to a surface facing a user in order to prevent the reflection of external light when the user sees an image. However, the circular polarization film may cause a light transmittance loss of at least 50%. Therefore, even when the organic light-emitting display apparatus is formed as a transparent display apparatus, 50% or more of a transmittance of the transmission image may be reduced.

The above information disclosed in this Background section is only for enhancement of understanding of the background of the invention and therefore it may contain information that does not form any part of the prior art nor what the prior art may suggest to a person of ordinary skill in the art.

### SUMMARY

Exemplary embodiments of the present invention relate to organic light-emitting display apparatus having reduced reflection of external light and decreased reduction in transmittance of a transmission image.

Additional features of the invention will be set forth in part in the description which follows, and in part will be apparent from the description, or may be learned by practice of the presented embodiments.

An exemplary embodiment of the present invention discloses an organic light-emitting display apparatus, including: a substrate including a first surface and a second surface opposite to each other; an organic emission unit disposed on the first surface of the substrate and including: an emission region configured to emit light; and a first transmission region configured to transmit external light; an encapsulation unit joined to the first surface of the substrate, the encapsulating unit configured to seal the organic emission unit from external air; a first functional layer configured to delay a phase of the external light; and a second functional layer configured to linearly polarize the external light, wherein the second function layer is disposed farther from the organic emission unit than the first functional layer and includes a second transmission region corresponding to the first transmission region.

An exemplary embodiment of the present invention also discloses an organic light-emitting display apparatus, including: a substrate including a first surface and a second surface opposite to each other; a plurality of pixels disposed on the first surface of the substrate each of the plurality of pixels respectively including: a first region including an emission region configured to emit light; and a second region including a first transmission region configured to transmit external light; a plurality of first electrodes, each of the plurality of first electrodes disposed respectively in the first regions of the pixels; an intermediate layer disposed on the plurality of first electrodes, the intermediate layer including an organic emission layer; a second electrode disposed on the intermediate layer, the second electrode disposed in the first region and the second region; an encapsulation unit joined to the first surface of the substrate; a first functional layer configured to delay a phase of the external light; and a second functional layer configured to linearly polarize the external light, wherein the second functional layer is disposed farther from the organic emission unit than the first functional layer, and includes a plurality of second transmission regions corresponding respectively to the first transmission regions.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic cross-sectional view illustrating an organic light-emitting display apparatus according to an exemplary embodiment of the present invention.

FIG. 2 is a schematic cross-section view illustrating an exemplary embodiment of the organic light-emitting display apparatus of FIG. 1.

FIG. 3 is a schematic cross-section view illustrating an exemplary embodiment of the organic light-emitting display apparatus of FIG. 1.

FIG. 4 is a schematic cross-section view illustrating an exemplary embodiment of an organic emission unit of FIGS. 2 and 3.

FIG. 5 is a partial cross-sectional view illustrating an exemplary embodiment of a portion I of FIG. 2.

FIG. 6 is a plan view illustrating an exemplary embodiment of a pixel of the organic emission unit.

FIG. 7 is a cross-sectional view taken along a line II-II of FIG. 6.

FIG. 8 is a partial cross-sectional view illustrating an exemplary embodiment of a second functional layer.

FIG. 9 is a partial cross-sectional view illustrating an exemplary embodiment of the second functional layer.

FIG. 10 is a partial cross-sectional view illustrating an exemplary embodiment of the second functional layer.

FIG. 11 is a partial cross-sectional view illustrating an exemplary embodiment of the portion I of FIG. 2.

FIG. 12 is a partial cross-sectional view illustrating an exemplary embodiment of the portion I of FIG. 2.

FIG. 13 is a partial cross-sectional view illustrating an exemplary embodiment of the portion I of FIG. 2.

FIG. 14 is a partial cross-sectional view illustrating an exemplary embodiment of the portion I of FIG. 2.

FIG. 15 is a partial cross-sectional view illustrating an exemplary embodiment of the portion I of FIG. 2.

FIG. 16 is a partial cross-sectional view illustrating an exemplary embodiment of the portion I of FIG. 2.

### DETAILED DESCRIPTION OF THE ILLUSTRATED EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items. Expressions such as “at least one of,” when preceding a list of elements, modify the entire list of elements and do not modify the individual elements of the list.

The present invention may include various embodiments and modifications, and exemplary embodiments thereof are illustrated in the drawings and will be described herein in detail. The effects and features of the present invention and the accomplishing methods thereof will become apparent from the following description of the embodiments, taken in conjunction with the accompanying drawings. However, the prevent invention is not limited to the embodiments described below, and may be embodied in various modes.

It will be understood that although the terms “first”, “second”, etc. may be used herein to describe various components, these components should not be limited by these terms. These terms are only used to distinguish one component from another.

As used herein, the singular forms “a,” “an” and “the” are intended to include the plural forms as well, unless the context clearly indicates otherwise.

It will be further understood that the terms “comprise”, “include” and “have” used herein specify the presence of stated features or components, but do not preclude the presence or addition of one or more other features or components.

It will be understood that when a layer, region, or component is referred to as being “formed on” another layer, region, or component, it may be directly or indirectly formed on the other layer, region, or component. That is, for example, intervening layers, regions, or components may be present.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Sizes of components in the drawings may be exaggerated for convenience of description. In other words, since sizes and thicknesses of components in the drawings are arbitrarily illustrated for convenience of description, the following embodiments are not limited thereto.

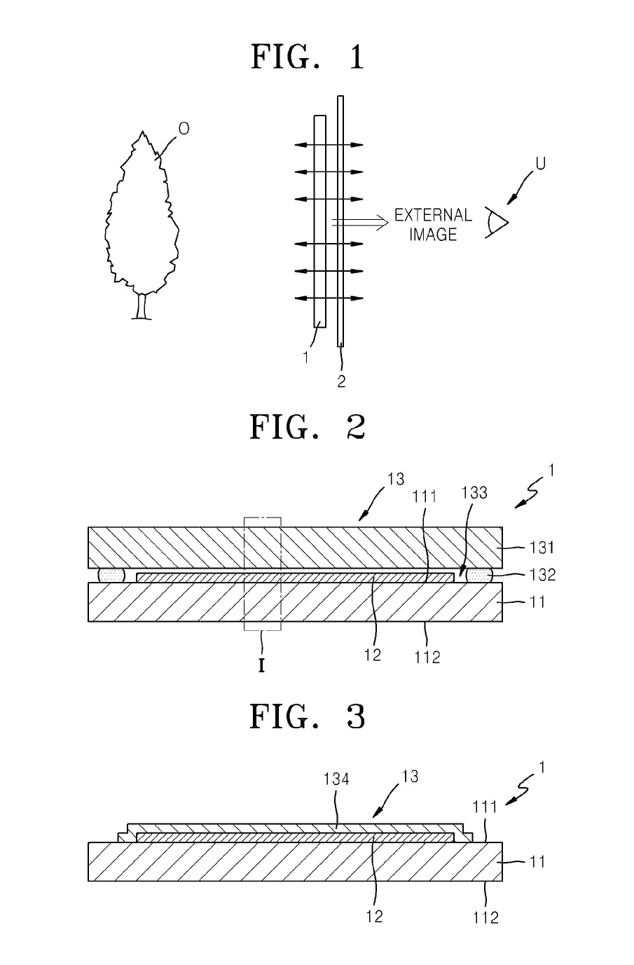

FIG. 1 is a schematic cross-sectional view illustrating an organic light-emitting display apparatus 1 according to an exemplary embodiment of the present invention.

Referring to FIG. 1, the organic light-emitting display apparatus 1 according to an exemplary embodiment of the present invention may emit an image toward a user U and also transmit external light in a thickness direction thereof. Therefore, the user U may see the image of an object 0 located on an opposite side through the organic light-emitting display apparatus 1. The organic light-emitting display apparatus 1 may further include a cover member 2 facing the user U. The cover member 2 may be formed of a material having a high light transmittance so that the user U may view both an emission image of the organic light-emitting display apparatus 1 and a transmission image of the object 0. Also, the cover member 2 may protect the organic light-emitting display apparatus 1 from an external impact. The cover member 2 may be formed of tempered glass and/or reinforced plastic.

FIGS. 2 and 3 are cross-section views illustrating exemplary embodiments of the organic light-emitting display apparatus 1.

Referring to FIG. 2, the organic light-emitting display apparatus 1 includes an organic emission unit 12 on a substrate 11.

The substrate 11 has a first surface 111 and a second surface 112 opposite to each other, and may be formed of glass and/or plastic. The substrate 11 may be transparent.

The organic emission unit 12 is formed or disposed on the first surface 111 of the substrate 11, and an encapsulation unit 13 is coupled to the first surface 111 of the substrate 11 to seal the organic emission unit 12 from external air. According to the exemplary embodiment of FIG. 2, the encapsulation unit 13 may be an encapsulation substrate 131.

The encapsulation substrate 131 may be formed of a transparent member. The encapsulation substrate 131 may be formed of glass and/or plastic. The substrate 11 and the encapsulation substrate 131 may be flexible.

Edges of the substrate 11 and the encapsulation substrate 131 are coupled by a sealing material 132, to seal a space 133 between the substrate 11 and the encapsulation substrate 131. A moisture absorbent or a filler may be disposed in the space 133.

Referring to FIG. 3, the encapsulating unit 13 may be a thin film encapsulation layer 134 (instead of the encapsulation substrate 131) formed or disposed on the organic emission unit 12 to protect the organic emission unit 12 from external air.

The thin film encapsulation layer 134 may include a plurality of inorganic layers and/or a mixture of an inorganic layer and an organic layer.

The organic layer of the thin film encapsulation layer 134 is formed of a polymer and may be a single layer or a layer stack formed of at least one of polyethylene terephthalate, polyimide, polycarbonate, epoxy, polyethylene, and polyacrylate. The organic layer may be formed of polyacrylate, and in detail, may include a polymerized monomer composition including a diacrylate-based monomer and/or a triacrylate-based monomer. The monomer composition may further include a monoacrylate-based monomer. Also, the monomer composition may further include a photoinitiator, such as trimethyl benzoyl diphenyl phosphine oxide (TPO), but exemplary embodiments of the present invention are not limited thereto.

The inorganic layer of the thin film encapsulation layer 134 may be a single layer or a layer stack including a metal oxide and/or a metal nitride. In detail, the inorganic layer may include at least one of SiNₓ, Al₂O₃, SiO₂, and TiO₂.

The top layer of the thin film encapsulation layer 134 that is exposed to an outside thereof may be formed of an inorganic layer in order to prevent intrusion of moisture into the organic emission unit 12.

The thin film encapsulation layer 134 may include at least one sandwich structure in which at least one organic layer is disposed between at least two inorganic layers. The thin film encapsulation layer 134 may include at least one sandwich structure in which at least one inorganic layer is disposed between at least two organic layers. The thin film encapsulation layer 134 may also include a sandwich structure in which at least one of sandwich structures above is disposed between at least two organic layers and/or two inorganic layers.

The thin film encapsulation layer 134 may include a first inorganic layer, a first organic layer, and a second inorganic layer sequentially formed or disposed on the organic emission unit 12.

The thin film encapsulation layer 134 may include a first inorganic layer, a first organic layer, a second inorganic layer, a second organic layer, and a third inorganic layer sequentially formed or disposed on the organic emission unit 12.

The thin film encapsulation layer 134 may also include a first inorganic layer, a first organic layer, a second inorganic layer, a second organic layer, a third inorganic layer, a third organic layer, and a fourth inorganic layer sequentially formed or disposed on the organic emission unit 12.

A halogenized metal layer including a lithium fluoride (LiF) may be additionally disposed between the organic emission unit 12 and the first inorganic layer. The halogenized metal layer may prevent the organic emission unit 12 from being damaged when the first inorganic layer is formed or disposed by sputtering or plasma deposition.

The first organic layer may be smaller than the second inorganic layer, and the second organic layer may be smaller than the third inorganic layer.

The first organic layer may be completely covered by the second inorganic layer, and the second organic layer may be completely covered by the third inorganic layer.

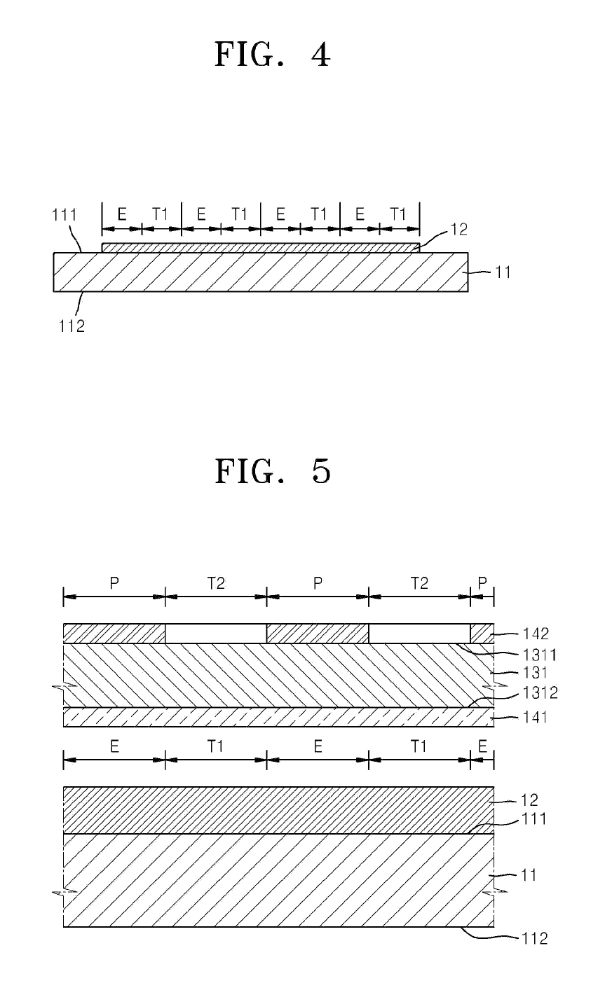

Referring to FIG. 4, the organic emission unit 12 of FIGS. 2 and 3 may include an emission region E emitting light and a first transmission region T1 transmitting external light.

The emission region E emits light, so the user may view an image formed by the organic emission unit 12. External light may pass through the first transmission region T1, so the user may view an image of an object that is disposed on an opposite side of the organic light-emitting display apparatus 1. Therefore, the substrate 11 may be transparent. FIG. 4 illustrates a schematic partition between the emission region E and the first transmission region T1 of the organic emission unit 12. FIG. 4 illustrates that the emission region E and the first transmission region T1 are uniformly formed or disposed over an entire area of the organic emission unit 12 continuously without being spaced apart from each other; however, exemplary embodiments of the present invention are not limited thereto. For example, the emission region E and the first transmission region T1 may be spaced apart from each other. This may be similarly applied to all exemplary embodiments descried herein.

FIG. 5 is a partial cross-sectional view illustrating an exemplary embodiment of a portion I of FIG. 2. According to the exemplary embodiment illustrated in FIG. 5, the organic emission unit 12 is formed or disposed on the first surface 111 of the substrate 11, and the encapsulation substrate 131 is disposed facing the organic emission unit 12. A first functional layer 141, which may also be referred to as a first optical layer 141, is formed or disposed on a second surface 1312 of the encapsulation substrate 131 facing the organic emission unit 12, and a second functional layer 142, which may be also referred to as a second optical layer 143, is formed or disposed on a first surface 1311 of the encapsulation substrate 131 that is opposite to the second surface 1312.

In the exemplary embodiment illustrated in FIG. 5, the organic emission unit 12, specifically, the emission region E of the organic emission unit 12 emits an image toward the encapsulation substrate 131. Thus, the organic emission unit 12 is a front emission type organic emission unit 12.

The first functional layer 141 may be configured to delay a phase of external light that enters from the first surface 1311 of the encapsulation substrate 131 into the encapsulation substrate 131. The first functional layer 141 may be a ¼ wavelength layer so that the first functional layer 141 may form a circular polarization layer in combination with the second functional layer 142.

The second functional layer 142 may be configured to linearly polarize the external light that enters from the first surface 1311 of the encapsulation substrate 131 into the encapsulation substrate 131. Thus, the second functional layer 142 may have a light absorption axis and a light transmission axis in respective directions. The second functional layer 142 may be disposed farther than the first functional layer 141 from the organic emission unit 12 in an emission direction of the light.

As for the external light entering from a user side of the encapsulation substrate 131 from where the user is viewing the image, the second functional layer 142 absorbs a light component in a direction along the light absorption axis and transmits a light component in a direction along the light transmission axis. The first functional layer 141 may convert the light component in the light transmission axis into circularly-polarized light rotated in one direction. The circularly-polarized light may be reflected by one of the electrodes of the organic emission unit 12. When reflected by one of the electrodes of the organic emission unit 12, the circularly-polarized light rotated in one direction becomes circularly-polarized light rotated in another direction. The first functional layer 141 may convert the circularly-polarized light rotated in another direction into linearly-polarized light in a direction perpendicular to the light transmission axis. The linearly-polarized light is then absorbed by the light absorption axis of the second functional layer 142 and thus does not transmit to the user side of the encapsulation substrate 131. Thus, the reflection of the external light to the user, who is seeing an emission image from the organic emission unit 12 at the user side of the encapsulation substrate 131, may be decreased, and a contrast of the emission image may be further improved.

In addition, a second transmission region T2 corresponding to the first transmission region T1 is formed or disposed in the second functional layer 142. Since the second functional layer 142 includes the light absorption axis, it significantly reduces the transmittance of light transmitted through the first transmission region T1 of the organic emission region T1. According to an exemplary embodiment of the present invention, the second transmission region T2 corresponding to the first transmission region T1 formed or disposed in the second functional layer 142, thereby decreasing the reduction of the transmittance of light transmitted through the organic emission unit 12.

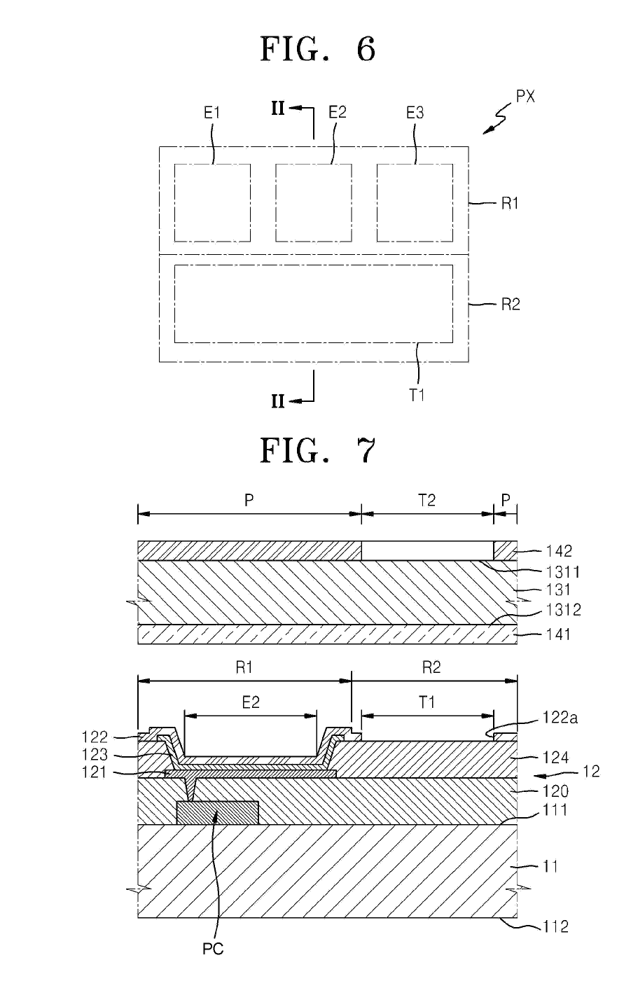

The organic emission unit 12 may include a plurality of pixels. FIG. 6 is a plan view illustrating an exemplary embodiment of a pixel PX among the plurality of pixels, and FIG. 7 is a cross-sectional view taken along a line II-II of FIG. 6.

Each pixel PX may include a first region R1 and a second region R2. The first region R1 may include a first emission region E1, a second emission region E2, and a third emission region E3 that emit light, and the second region R2 may include a first transmission region T1 that transmits the external light. For example, the first emission region E1, the second emission region E2, and the third emission region E3 may be respectively a red subpixel, a green subpixel, and a blue subpixel. FIG. 6 illustrates that the pixel PX includes only three emission regions. However, exemplary embodiments of the present invention are not limited thereto, and the pixel PX may further include a subpixel that emits light of another color.

For example, a single pixel PX may include the subpixels emitting red, green, blue, and/or white lights, and the single pixel PS may form a white light by a mixture of the lights. Each of the subpixels may further include a color converting layer or a color filter to convert a white light of into a light of another color.

The red, greed, and blue colors are merely exemplary, and the present invention is not limited thereto. Exemplary embodiments of the present invention may include any combination of other various colors, which is capable of emitting a white light, may be used in addition to a combination of red, green, and blue colors.

Referring to FIG. 7, an organic light-emitting device and a pixel circuit PC may be disposed in the first region R1. The pixel circuit PC may include a switching thin film transistor connected to a scan line and a data line, a driving thin film transistor connected to the switching thin film transistor and a Vdd line, and a capacitor connected to the switching thin film transistor and the driving thin film transistor.

A first insulating layer 120 is formed or disposed to cover the pixel circuit PC. The first insulating layer 120 may be a single layer or a plurality of insulating layers having a planarized top surface. The first insulating layer 120 may be formed of an inorganic material and/or an organic material.

As illustrated in FIG. 7, a first electrode 121 electrically connected to the pixel circuit PC is formed or disposed on the first insulating layer 120. The first electrode 121 is formed or disposed in an island shape.

A second insulating layer 124 is formed or disposed on the first insulating layer 120 to cover an edge of the first electrode 121. The second insulating layer 124 may be formed of an organic material such as polyimide and/or acryl.

An intermediate layer 123 including an organic emission layer is formed or disposed on the first electrode 121, and a second electrode 122 is formed or disposed to cover the intermediate layer 123, thereby forming an organic light-emitting device.

The intermediate layer 123 may include a low-molecular-weight organic material and/or high-molecular-weight organic material.

The intermediate layer 123 may include a first intermediate layer, a second intermediate layer, and an organic emission layer disposed between the first intermediate layer and the second intermediate layer.

The first intermediate layer is disposed between the organic emission layer and the first electrode 121, and may include a hole injection layer (HIL) and/or a hole transport layer (HTL).

The second intermediate layer is disposed between the organic emission layer and the second electrode 122, and may include an electron transport layer (ETL) and/or an electron injection layer (EIL).

The organic emission layer may be formed or disposed in each of the red, green, and blue subpixels, and the first intermediate layer and the second intermediate layer may be commonly disposed in all of the pixels.

The HIL may include at least one of a phthalocyanine compound, such as copper phthalocyanine, and starburst-type amine including at least one of TCTA, m-MTDATA, and m-MTDAPB.

The HTL may include at least one of N,N′-bis(3-methylphenyl)-N,N′-diphenyl-[1,1-biphenyl]-4,4′-diamine(TPD), and N,N′-di(naphthalene-1-yl)-N,N′-diphenyl benzidine(α-NPD).

The ETL may include Alq₃.

The EIL may include at least one of LiF, NaCl, CsF, Li₂O, BaO, and Liq.

The organic emission layer may include a host material and/or a dopant material.

The host material may include at least one of tris(8-hydroxyquinolinato)aluminium (Alq3), 9,10-di(naph-2-tyl)anthracene (ADN), 2-tert-butyl-9,10-di(naph-2-tyl)anthracene (TBADN), 4,4′-bis(2,2-diphenylethenyl) biphenyl (DPVBi), and 4,4′-bis[2,2-di(4-methylphenyl)-ethen-1-yl] biphenyl (p-DMDPVBi).

The dopant material may include at least of 4,4′-bis[4-(di-p-tolylamino)styrl]biphenyl (DPAVBi), 9,10-di(naph-2-tyl)anthracene (ADN), and 2-tert-butyl-9,10-di(naph-2-tyl)anthracene (TBADN).

For example, the first electrode 121 may function as an anode, and the second electrode 122 may function as a cathode. The first electrode 121 may also function as a cathode, and the second electrode 122 may function as an anode.

When the first electrode 121 is an anode, the first electrode 121 may include at least one of ITO, IZO, ZnO, and In₂O₃ that has a high work function. When an image is formed towards the encapsulation substrate 131, the first electrode 121 may further include a reflection layer (not illustrated) including at least one of Ag, Mg, Al, Pt, Pd, Au, Ni, Nd, Ir, Cr, Li, Yb, Co, Sm, and Ca.

When the second electrode 122 is a cathode, the second electrode 122 may include may include at least one of a metal such as Ag, Mg, Al, Pt, Pd, Au, Ni, Nd, Ir, Cr, Li, Yb, Co, Sm, and Ca. The second electrode 122 may be configured to transmit the light emitted from the intermediate layer 123 in order to smoothly form a second image. Accordingly, the second electrode 122 may include a thin film formed of Mg and/or Mg alloy. The second electrode 122 may include a thin film formed of Ag and/or Ag alloy that have a higher light transmittance. The second electrode 122 may also include a stack or a co-deposition of Mg and/or Mg alloy and Ag and/or Ag alloy. When the organic light-emitting display apparatus is a rear emission type, as described later, the second electrode 122 may be thickly formed or disposed to provide light reflection.

Unlike the first electrode 121, the second electrode 122 may be formed as a common electrode to apply a common voltage to all the pixels. The second electrode 122 may be formed by co-deposition by using an open mask. Thus, the second electrode 122 may be disposed in both the first region R1 and the second region R2.

The first region R1 includes a second emission region E2, and the second region R2 includes a first transmission region T1. The second emission region E2 emits an image by the organic light-emitting device including a stack of the first electrode 121, the intermediate layer 123, and the second electrode 122. A transmission image formed under the substrate 11 may be transmitted through the first transmission region T1, so that the user may view the transmission image on the encapsulation substrate 131.

Also, in order to increase the transmittance of external light through the first transmission region T1, a transmission window 122a may be formed by forming an opening in the second electrode 122 formed of a metal having a high reflectance. The transmission window 122a may be formed corresponding to the first transmission region T1. As illustrated in FIG. 6, when the first transmission region T1 is formed continuously adjacent to the three subpixels, (i.e., the first emission region E1, the second emission region E2, and the third emission region E3) the transmission window 122a, which is formed in the second electrode 122 to correspond to the shape of the first transmission region T1, may also be formed continuously adjacent to the three subpixels. FIG. 7 illustrates that the transmission window 122a is formed only in the second electrode 122. However, exemplary embodiments of the present invention are not limited thereto, and an opening connected to the transmission window 122a may be further formed in at least one of the first insulating layer 120 and the second insulating layer 124. Accordingly, the transmittance of external light through the first transmission region T1 may be increased. The pixel structure of the organic emission unit illustrated in FIGS. 6 and 7 may be similarly applied to all exemplary embodiments of the present invention.

Also, in each pixel PX, the second transmission region T2 may be formed or disposed in the second functional layer 142 to increase the transmittance of external light.

Referring to FIG. 7, the first functional layer 141 is free of a transmission region because the first functional layer 141 has a high light transmittance. However, exemplary embodiments of the present invention are not limited thereto, and a transmission region corresponding to the first transmission region T1 may also be formed in the first functional layer 141. The transmission region formed in the first functional layer 141 may be formed in the shape of an opening.

The first functional layer 141 may be formed by attaching a ¼ wavelength film or a 1/2 wavelength film to the second surface 1312 of the encapsulation substrate 131 by using an adhesive. However, exemplary embodiments of the present invention are not limited thereto, and the first functional layer 141 may be formed by deposition on the second surface 1312 of the encapsulation substrate 131.

For example, the first functional layer 141 may be formed by using a birefringent material or a material that is formed by artificially giving birefringent characteristics to a non-birefringent material.

Birefringent characteristics may be artificially given to a non-birefringent material by growing an alkali metal oxide having high polarizability in a direction in which a crystal is inclined. In this case, the alkali metal oxide may be CaO and/or BaO.

That is, inclined crystal growth may be generated by depositing the alkali metal oxide on the second surface 1312 of the encapsulation substrate 131 inclined by a predetermined angle with respect to the vertical direction. The inclination angle may be about 50° to about 80°.

When inclined deposition is attempted with an inclination angle of about 50° or less, growth in an inclination direction may not be properly generated. Also, in order to achieve a phase delay effect, the inclination angle may be about 80° or less. When the inclination angle is greater than about 80°, a phase delay effect may be slight.

The first functional layer 141 formed of inclined deposition of CaO and/or BaO may become a ¼ wavelength layer or a ½ wavelength layer depending on a thickness thereof.

In a case where the first functional layer 141 is formed of CaO, when it is deposited to a thickness of about 2 μm to about 5 μm, it may be a 1/4 wavelength layer; and when it is deposited to a thickness of about 4 μm to about 19 μm, it may be a ½ wavelength layer. When the first functional layer 141 includes a combination of a ¼ wavelength layer and a ½ wavelength layer, right-handed circular polarization and left-handed circular polarization may be freely set and a linear polarization angle may be set.

When the deposition is performed such that a crystal growth direction is inclined with respect to the second surface 1312 of the encapsulation substrate 131, the first functional layer 141 is formed in such a manner that a plurality of fine pillar-shaped columns may have inclined arrangement on the second surface 1312 of the encapsulation substrate 131.

The second functional layer 142 may also be formed or disposed by deposition on the first surface 1311 of the encapsulation substrate 131.

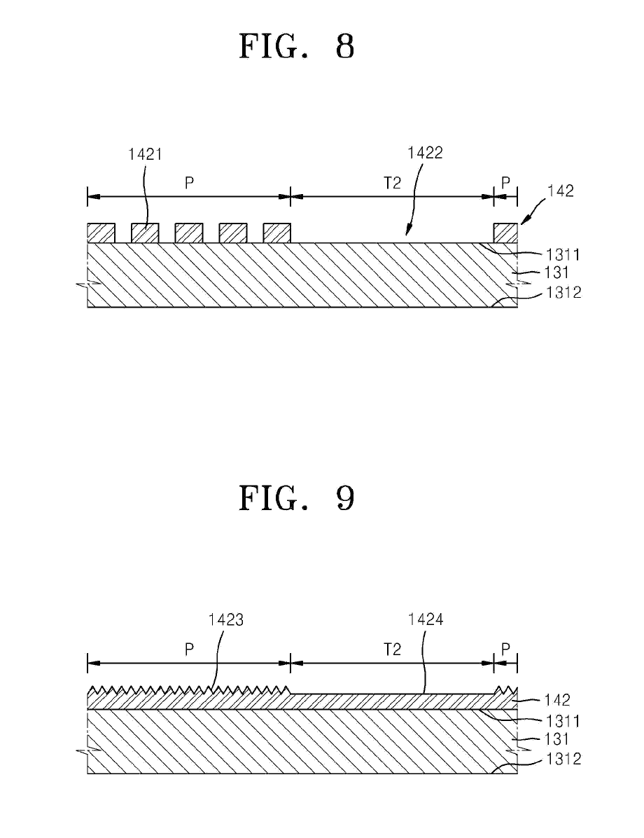

FIG. 8 is a partial cross-sectional view illustrating an exemplary embodiment of the second functional layer 142.

The second functional layer 142 may include a plurality of wire grids 1421 that are disposed spaced apart from each other by a distance on the first surface 1311 of the encapsulation substrate 131. The width of each wire grid 1421 may be about tens of nm, disposed in a period of about tens or hundreds of nm.

The wire grids 1421 may include photochromic materials.

The photochromic materials may include at least one of, but are not limited to, naphthopyran compounds, spirooxazine compounds, and spiropyran compounds.

Examples of the spiropyran compounds may include at least one of 1′,3′,3′-trimethylspiro(2H-1-benzopyran-2,2′-indoline), 1′,3′,3′-trimethylspiro-8-nitro(2H-1-benzopyran-2,2′-indoline), 1′,3′,3′-trimethyl-6-hydroxyspiro(2H-1-benzopyran-2,2′-indoline), 1′,3′,3′-trimethylspiro-8-methoxy(2H-1-benzopyran-2,2′-indoline), 5′-chloro-1′,3′,3′-trimethyl-6-nitrospiro(2H-1-benzopyran-2,2′-indoline), 6,8-dibromo-1′,3′,3′-trimethylspiro(2H-1-benzopyran-2,2′-indoline), 6,8-dibromo-1′,3′,3′-trimethylspiro(2H-1-benzopyran-2,2′-indoline), 8-ethoxy-1′,3′,3′,4,7-pentamethylspiro(2H-1-benzopyran-2,2′-indoline), 5′-chloro-1′,3′,3′-trimethylspiro-6,8-dinitro(2H-1-benzopyran-2,2′-indoline), 3,3,1-diphenyl-3H-naphtho-(2,1-13) pyran, 1,3,3-triphenylspiro[indoline-2,3′-(3H)-naphtho(2,1-b)pyran], 1-(2,3,4,5,6-pentamethylbenzyl)-3,3-dimethylspiro[indoline-2,3′-(3H)-naphtho(2,1-b)pyran], 1-(2-methoxy-5-nitrobenzyl)-3,3-dimethylspiro[indoline-2,3′-naphtho(2,1-b)pyran], 1-(2-nitrobenzyl)-3,3-dimethylspiro[indoline-2,3′-naphtho(2,1-b)pyran], 1-(2-naphtylmethyl)-3,3-dimethylspiro[indoline-2,3′-naphtho(2,1-b)pyran], and 1,3,3-trimethyl-6′-nitro-spiro[2H-1-benzopyran-2,2′-(2H)-indole].

Examples of the spirooxazine compounds may include at least one of 1,3,3-trimethylspiro[indolino-2,3′-(3H)naphtho(2,1-b)(1,4)oxazine], 5-methoxy-1,3,3-trimethylspiro[indolino-2,3′-(3H)naphtho(2,1-b)(1,4)oxazine], 5-chloro-1,3,3-trimethylspiro[indolino-2,3′-(3H)naphtho(2,1-b)(1,4)oxazine], 4,7-diethoxy-1,3,3-trimethylspiro[indolino-2,3′-(3H)naphtho(2,1-b)(1,4)oxazine], 5-chloro-l-butyl-3,3-dimethylspiro[indolino-2,3′-(3H)naphtho(2,1-b)(1,4)oxazine], 1,3,3,5-tetramethyl-9′-ethoxyspiro[indolino-2,3′-(3H)naphtho(2,1-b)(1,4)oxazine], 1-benzyl-3,3-dimethylspiro[indoline-2,3′-(3H)naphtho(2,1-b)(1,4)oxazine], 1-(4-methoxybenzyl)-3,3-dimethylspiro[indoline-2,3′-(3H)naphtho(2,1-b)(1,4)oxazine], 1-(2-methylbenzyl)-3,3-dimethylspiro[indoline-2,3′-(3H)naphtho(2,1-b)(1,4)oxazine], 1-(3,5-dimethylbenzyl)-3,3-dimethylspiro[indoline-2,3′-(3H)naphtho(2,1-b)(1,4)oxazine], 1-(4-chlorobenzyl)-3,3-dimethylspiro[indoline-2,3′-(3H)naphtho(2,1-b)(1,4)oxazine], 1-(4-bromobenzyl)-3,3-dimethylspiro[indoline-2,3′-(3H)naphtho(2,1-b)(1,4)oxazine], 1-(2-fluorobenzyl)-3,3-dimethylspiro[indoline-2,3′-(3H)naphtho(2,1-b)(1,4)oxazine], 1,3,5,6-tetramethyl-3-ethylspiro [indoline-2,3′-(3H)pyrido(3,2-f)(1,4)benzooxazine], 1,3,3,5,6-pentamethylspiro [indoline-2,3′-(3H)pyrido(3,2-f)(1,4)-benzooxazine], 6′-(2,3-dihydro-1H-indole-1-yl)-1,3-dihydro-3,3-dimethyl-1-propyl-spiro [2H-indole-2,3′-(3H)naphtho(2,1-b)(1,4)oxazine], 6′-(2,3-dihydro-1H-indole-1-yl)yl)-1,3-dihydro-3,3-dimethyl-1-(2-methylpropyl)-spiro [2H-indole-2,3′-(3H)naphtho(2,1-b)(1,4)oxazine], 1,3,3-trimethyl-1-6′-(2,3-dihydro-1H-indole-1-yl)spiro [2H-indole-2,3′-(3H)naphtho(2,1-b)(1,4)oxazine], 1,3,3-trimethyl-6′-(1-piperidyl)spiro [2H-indole-2,3′-(3H)naphtho(2,1-b)(1,4)oxazine], 1,3,3-trimethyl-6′-(1-piperidyl)-6-(trifluoromethyl)spiro [2H-indole-2,3′-(3H)naphtho(2,1-b)(1,4)oxazine], and 1,3,3,5,6-pentamethyl-spiro [2H-indole-2,3′-(3H)naphtho(2,1-b)(1,4)oxazine].

Examples of the naphthopyran compounds may include at least one of 3,3-diphenyl-3H-naphtho(2,1-b)pyran, 2,2-diphenyl-2H-naphtho(1,2-b)pyran,3-(2-fluorophenyl)-3-(4-methoxyphenyl)-3H-naphtho(2,1-b)pyran, 3-(2-methyl-4-methoxyphenyl)-3-(4-ethoxyphenyl)-3H-naphtho(2,1-b)pyran, 3-(2-furyl)-3-(2-fluorophenyl)-3H-naphtho(2,1-b)pyran, 3-(2-thienyl)-3-(2-fluoro-4-methoxyphenyl)-3H-naphtho(2,1-b)pyran, 3-[2-(1-methylpyrrolyl)]-3-(2-methyl-4-methoxyphenyl)-3H-naphtho(2,1-b)pyran, spiro[bicyclo[3.3.1]nonane-9,3′-3H-naphtho(2,1-b)pyran], spiro[bicyclo[3.3.1]nonane-9-2′-3H-naphtho(2,1-b)pyran]4-[4-[6-(4-morpholinyl)-3-phenyl-3H-naphtho(2,1-b)pyran-3-yl]phenyl]-morpholine, 4-[3-(4-methoxyphenyl)-3-phenyl-3H-naphtho(1-b)pyran-6-yl]-morpholine, 4-[3,3-bis(4-methoxyphenyl)-3H-naphtho(2,1-b)pyran-6-yl]-morpholine,4-[3-phenyl-3-[4-(1-piperidyl)phenyl]-3H-naphtho(2.1-b)pyran-6-yl]-morpholine, and 2,2-diphenyl-2H-naphtho(2,1-b)pyran. A bis-(N,N-diethylaminoethyl)perylene-3,4,9,10 may also be used.

The photochromic material maintains a transparent state at night or under low-ultraviolet or low-brightness external light such as indoor light, but may change its color and become an opaque state under high-ultraviolet or high-brightness external light such as solar light. Also, the photochromic material may reversibly change from a transparent state to an opaque state.

The wire grids 1421 may be formed of a resin containing the photochromic material as a coloring material, and may be formed and patterned on the encapsulation substrate 131.

FIG. 8 illustrates that the wire grids 1421 are formed in the shape of a single layer, but exemplary embodiments of the present invention is not limited thereto. The wire grits 1421 may further include a transparent material layer disposed before and/or after a layer containing the photochromic material.

By properly selecting the photochromic, the wire grids 1421 may color-change under solar light and may maintain a transparent state under indoor light or at night.

The wire grid 1421 may be formed by co-deposition of graphite and metal. The graphite may be general graphite, and may be CN and/or CH-based graphite into which nitrogen and/or hydrogen is injected during deposition. The metal may be at least one of Al, Ag, W, and Au.

The metal may be contained in the graphite by using the above co-deposition process and/or by doping a graphite layer with the metal. Also in this case, the final content of the metal is set to 5 wt % or less to reduce the reflection by the metal.

The graphite layer mixed with the metal may be nano-patterned by a dry etching process using SiO₂ and/or SiNₓ as a hard mask and a photoresist (PR) process.

The wire grids 1421 may be formed by forming a metal layer on the first surface 1311 of the encapsulation substrate 131 and then forming a low-reflection layer on the metal layer. Accordingly, the reflection of external light on the surface of the wire grids 1421 may be reduced. The low-reflection layer may include at least one of CdSe, CdTe, and ruthenium.

The wire grids 1421 may also be formed as an overhand structure by a metal such as Al, Au, Ag, and/or W. After the overhand-structure wire grids 1421 are formed, the surfaces thereof are chemically blackened. When the wire grids 1421 are formed of aluminum, an oxide layer on a surface thereof is removed by acid and then the surface is blackened by a solution in which water is mixed with 5 mL nitric acid, 25 g copper nitride, and 10 g potassium permanganate. Accordingly, a reflection of external light on the wire grids 1421 having the above structure may be reduced.

When the second functional layer 142 includes the wire grids 1421, an opening region 1422 that is free of the wire grid may be formed in the second transmission region T2.

FIG. 9 is a partial cross-sectional view illustrating an exemplary embodiment of the second functional layer 142. As illustrated in FIG. 9, the second functional layer 142 may include an alignment portion 1423 and the second transmission region T2 including a non-alignment portion 1424. The alignment portion 1423 may be formed by depositing a photochromic material and then rubbing the disposed photochromic material. The non-alignment portion 1424 corresponds to an unrubbed region.

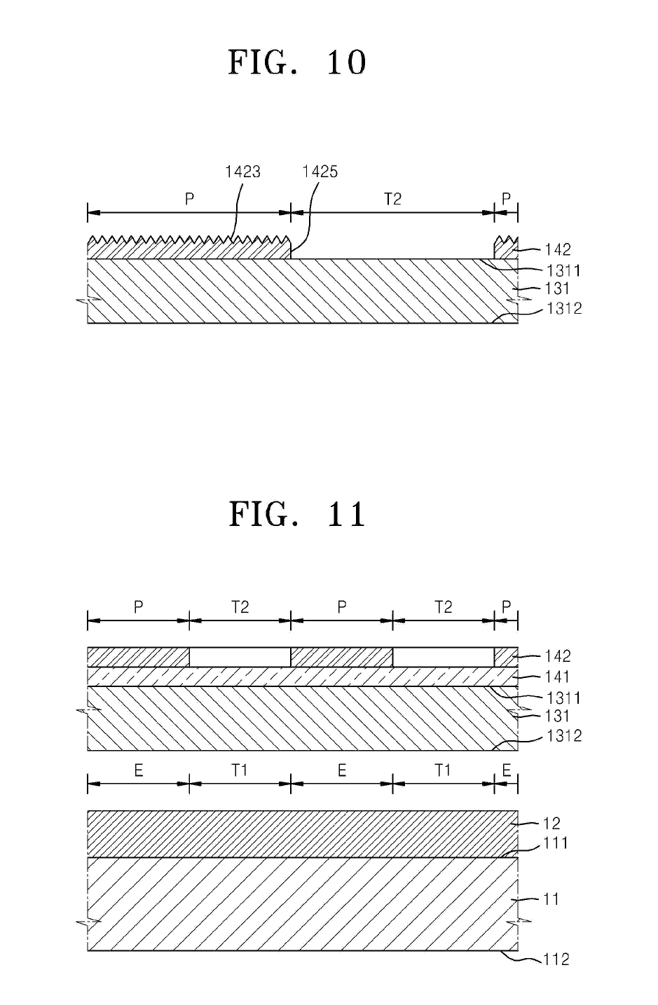

FIG. 10 is a partial cross-sectional view illustrating an exemplary embodiment of the second functional layer 142. Referring to FIG. 10, the second functional layer 142 may include an alignment portion 1423 and the second transmission region T2 including an opening region 1425.

The above exemplary embodiments of the first functional layer 141 and the second functional layer 142 may be similarly applied to all exemplary embodiments of the present invention.

Referring to the above exemplary embodiments, the first functional layer 141 is formed or disposed on the second surface 1312 of the encapsulation substrate 131, and the second functional layer 142 is formed or disposed on the first surface 1311 of the encapsulation substrate 131. However, exemplary embodiments of the present invention are not limited thereto, and various combinations are possible as described below.

FIG. 11 is a partial cross-sectional view illustrating an exemplary embodiment of the portion I of FIG. 2. Redundant descriptions of the same configurations as the above exemplary embodiments will be omitted hereinafter.

In the exemplary embodiment illustrated in FIG. 11, the first functional layer 141 is formed or disposed on the first surface 1311 of the encapsulation substrate 131, and then the second functional layer 142 is formed or disposed on the first functional layer 141. Also in this case, the user located over the encapsulation substrate 131 may view an image emitted from the organic emission unit 12 with reduced reflection of external light, and may view a transmission image of an object located under the substrate 11 through the second transmission region T2 with decreased reduction in transmittance.

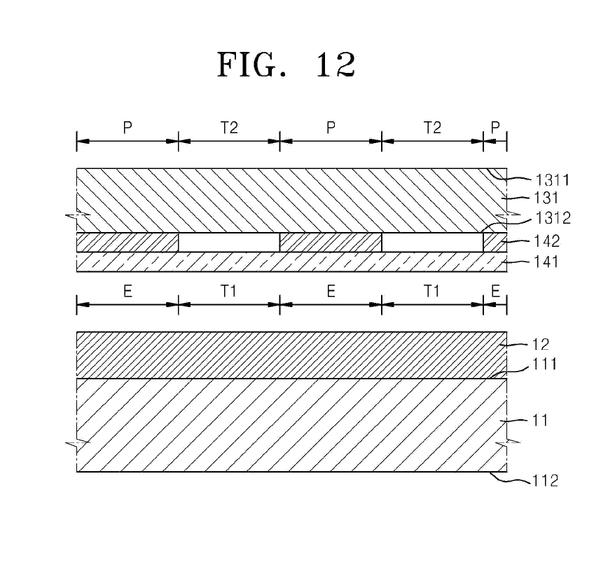

FIG. 12 is a partial cross-sectional view illustrating an exemplary embodiment of the portion I of FIG. 2. In the exemplary embodiment illustrated in FIG. 12, the second functional layer 142 is formed or disposed on the second surface 1312 of the encapsulation substrate 131, and then the first functional layer 141 is formed or disposed on a surface of the second functional layer 142 that faces the organic emission unit 12. Accordingly, the user located over the encapsulation substrate 131 may view an image emitted from the organic emission unit 12 with reduced reflection of external light, and may view a transmission image of an object located under the substrate 11 through the second transmission region T2 with decreased reduction in transmittance.

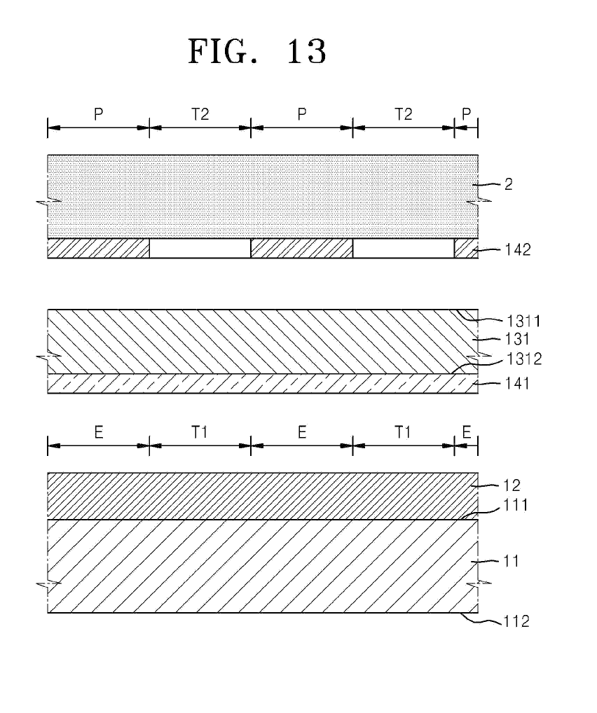

FIG. 13 is a partial cross-sectional view illustrating an exemplary embodiment of the portion I of FIG. 2. In the exemplary embodiment illustrated in FIG. 13, the first functional layer 141 is formed or disposed on the second surface 1312 of the encapsulation substrate 131, and then the second functional layer 142 is formed or disposed on an inner surface of the cover member 2, facing the encapsulation substrate 131. Also in this case, the user located over the cover member 2 may view an image emitted from the organic emission unit 12 with reduced reflection of external light, and may view a transmission image of an object located under the substrate 11 through the second transmission region T2 with decreased reduction in transmittance.

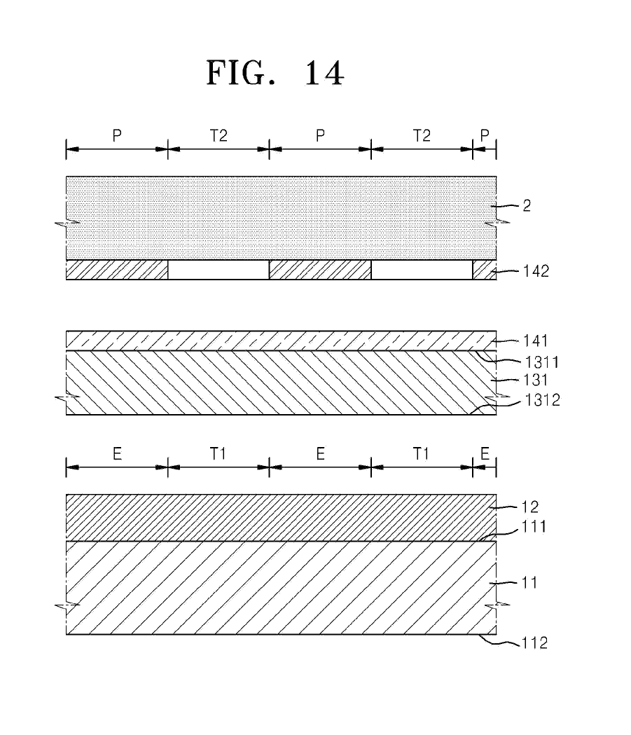

FIG. 14 is a partial cross-sectional view illustrating an exemplary embodiment of the portion I of FIG. 2. In the exemplary embodiment illustrated in FIG. 14, the first functional layer 141 is formed or disposed on the first surface 1311 of the encapsulation substrate 131, and the second functional layer 142 is formed or disposed on an inner surface of the cover member 2 facing the encapsulation substrate 131. Also in this case, the user located over the cover member 2 may view an image emitted from the organic emission unit 12 with reduced reflection of external light, and may view a transmission image of an object located under the substrate 11 through the second transmission region T2 with decreased reduction in transmittance.

The above-described exemplary embodiments illustrate a front emission type organic emission unit 12 that emits light toward the encapsulation substrate 131. However, exemplary embodiments of the present invention is not limited thereto, and may also be similarly applied to a rear emission type organic emission unit 12 that emits light toward the substrate 11.

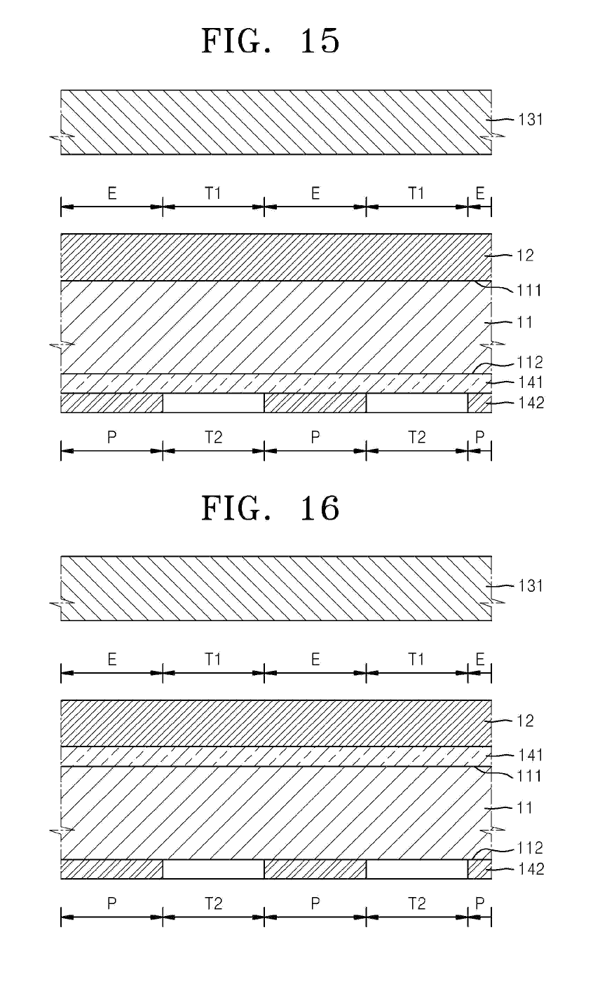

FIG. 15 is a partial cross-sectional view illustrating an exemplary embodiment of the portion I of FIG. 2. In the exemplary embodiment illustrated in FIG. 15, the first functional layer 141 is formed or disposed on the second surface 112 of the substrate 11, and the second functional layer 142 is formed or disposed on the bottom surface of the first functional layer 141. Accordingly, the user located under the substrate 11 may view an image emitted from the organic emission unit 12 with less reflection of external light, and may view a transmission image of an object located over the encapsulation substrate 131 through the second transmission region T2 with decreased reduction in transmittance.

FIG. 16 is a partial cross-sectional view illustrating an exemplary embodiment of the portion I of FIG. 2. In the exemplary embodiment illustrated in FIG. 16, the first functional layer 141 is formed or disposed on the first surface 111 of the substrate 11, and the second functional layer 142 is formed or disposed on the second surface 112 of the substrate 11. The organic emission unit 12 may be formed or disposed on the top surface of the first functional layer 141. In this case, the user located under the substrate 11 may view an image emitted from the organic emission unit 12 with less reflection of external light, and may view a transmission image of an object located over the encapsulation substrate 131 through the second transmission region T2 with decreased reduction in transmittance.

Although not illustrated, the second functional layer 142 may be first formed or disposed on the first surface 111 of the substrate 11 and the first functional layer 141 may be formed or disposed on the second functional layer 142, and then the organic emission unit 12 may be formed or disposed on the first functional layer 141.

In the above-described exemplary embodiments, the encapsulation unit 13 is the encapsulation substrate 131 as illustrated in FIG. 2. However, exemplary embodiments of the present invention are not limited thereto, and the encapsulation unit 13 may be the thin film encapsulation layer 134 as illustrated in FIG. 3.

As described above, according to the one or more of the above exemplary embodiments of the present invention, an image emitted from the organic emission unit may be seen with a high contrast with reduced reflection of external light. Also, since the reduction in a transmittance of a transmission image passing through the organic light-emitting display apparatus is decreased, the transmission image may be smoothly seen by the user.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments of the present invention have been described with reference to the figures, it will be understood by those of ordinary skill in the art that various changes in form and details may be made therein without departing from the spirit and scope of the present invention as defined by the following claims.

What is claimed is:

1. An organic light-emitting display apparatus, comprising:
a substrate comprising a first surface and a second surface opposite to each other;
an organic emission unit disposed on the first surface of the substrate and comprising:
an emission region configured to emit light; and
a first transmission region configured to transmit external light;
an encapsulation unit joined to the first surface of the substrate, the encapsulation unit configured to seal the organic emission unit from external air;
a first optical layer configured to delay a phase of the external light; and
a second optical layer configured to linearly polarize the external light,
wherein the second optical layer is disposed farther from the organic emission unit than the first optical layer and comprises a second transmission region corresponding to the first transmission region.

2. The organic light-emitting display apparatus of claim 1, wherein the second optical layer is disposed on the second surface of the substrate.

3. The organic light-emitting display apparatus of claim 1, wherein the second optical layer is disposed on the first surface of the substrate.

4. The organic light-emitting display apparatus of claim 1, wherein the second optical layer is disposed on a surface of the encapsulation unit that faces the substrate.

5. The organic light-emitting display apparatus of claim 1, wherein the second optical layer is disposed on a surface opposite to a surface of the encapsulation unit that faces the substrate.

6. The organic light-emitting display apparatus of claim 1, further comprising:
a cover member disposed to face the substrate or the encapsulation unit,
wherein the second optical layer is disposed on a surface of the cover member.

7. The organic light-emitting display apparatus of claim 1, wherein the second optical layer further comprises an opening disposed in the second transmission region.

8. An organic light-emitting display apparatus, comprising:
a substrate comprising a first surface and a second surface opposite to each other;
a plurality of pixels disposed on the first surface of the substrate, each of the plurality of pixels respectively comprising:
a first region comprising an emission region configured to emit light; and
a second region comprising a first transmission region configured to transmit external light;
a plurality of first electrodes disposed respectively in the first regions of the pixels;
an intermediate layer disposed on the plurality of first electrodes, the intermediate layer comprising an organic emission layer;
a second electrode disposed on the intermediate layer and disposed in the first region and the second region;
an encapsulation unit joined to the first surface of the substrate;
a first optical layer configured to delay a phase of the external light; and
a second optical layer configured to linearly polarize the external light,
wherein the second optical layer is disposed farther from the organic emission unit than the first optical layer, and comprises a plurality of second transmission regions corresponding respectively to the first transmission regions.

9. The organic light-emitting display apparatus of claim 8, wherein the second optical layer is disposed on the second surface of the substrate.

10. The organic light-emitting display apparatus of claim 8, wherein the second optical layer is disposed on the first surface of the substrate.

11. The organic light-emitting display apparatus of claim 8, wherein the second optical layer is disposed on a surface of the encapsulation unit that faces the substrate.

12. The organic light-emitting display apparatus of claim 8, wherein the second optical layer is disposed on a surface opposite to a surface of the encapsulation unit that faces the substrate.

13. The organic light-emitting display apparatus of claim 8, further comprising:
a cover member disposed to face the substrate or the encapsulation unit,
wherein the second optical layer is disposed on a surface of the cover member.

14. The organic light-emitting display apparatus of claim 8, wherein the second optical layer further comprises an opening corresponding to the second transmission region.
